(19) United States
(12) Patent Application Publication
(10) Pub. No.: US 2026/0006928 A1
(43) Pub. Date: Jan. 1, 2026

(54) SOLID-STATE IMAGE SENSOR

(71) Applicant: VisEra Technologies Company Limited, Hsin-Chu City (TW)

(72) Inventors: Chen-Yu LEE, Hsin-Chu City (TW); Zong-Ru TU, Hsin-Chu City (TW)

(21) Appl. No.: 18/754,903

(22) Filed: Jun. 26, 2024

(51) Int. Cl. H01L 27/146

(52) U.S. Cl. CPC H10F 39/806; H10F 39/024; H10F 39/182; H10F 39/8053; H10F 39/8063

(57) ABSTRACT

A solid-state image sensor is provided. The solid-state image sensor includes a first photoelectric conversion element and a second photoelectric conversion element adjacent to the first photoelectric conversion element. The solid-state image sensor also includes a color filter layer disposed above the first photoelectric conversion element and the second photoelectric conversion element. The solid-state image sensor further includes a converging structure and a diverging structure disposed on the color filter layer. The converging structure corresponds to the first photoelectric conversion element. The diverging structure corresponds to the second photoelectric conversion element.

### BACKGROUND OF THE INVENTION

### Field of the Invention

The present disclosure relates to a solid-state image sensor, and, in particular, to a solid-state image sensor that includes a converging structure and a diverging structure that respectively correspond to different photoelectric conversion elements.

### Description of the Related Art

Solid-state image sensors (e.g., complementary metal-oxide semiconductor (CMOS) image sensors) have been widely used in various image-capturing apparatuses such as digital still-image cameras, digital video cameras, and the like. Signal electric charges may be generated according to the amount of light received in the light-sensing portion (e.g., photoelectric conversion element) of the solid-state image sensor. In addition, the signal electric charges generated in the light-sensing portion may be transmitted and amplified, whereby an image signal is obtained.

High dynamic range (HDR) technology realizes crisp image capture, even with extremely bright and dark areas in one scene. Moreover, the HDR function not only solves the LED flicker mitigation (LFM) issue but it can also help detect and manage complex ambient light profiles. However, in traditional solid-state image sensors, it is more difficult to achieve a high dynamic range.

### BRIEF SUMMARY OF THE INVENTION

According to some embodiments of the present disclosure, the solid-state image sensor includes a converging structure and a diverging structure respectively corresponding to different photoelectric conversion elements. This enhances the signal difference of the photoelectric conversion elements, thereby achieving a high dynamic range.

An embodiment of the present disclosure provides a solid-state image sensor. The solid-state image sensor includes a first photoelectric conversion element and a second photoelectric conversion element adjacent to the first photoelectric conversion element. The solid-state image sensor also includes a color filter layer disposed above the first photoelectric conversion element and the second photoelectric conversion element. The solid-state image sensor further includes a converging structure and a diverging structure disposed on the color filter layer. The converging structure corresponds to the first photoelectric conversion element. The diverging structure corresponds to the second photoelectric conversion element.

In some embodiments, the diverging structure includes pillars.

In some embodiments, the number of the pillars is four, and the four pillars are arranged symmetrically and adjacent to centers of four sides of the second photoelectric conversion element in a top view, so that diffraction occurs when light passes through the pillars.

In some embodiments, the pillars are solid transparent cubes, and each of the pillars is formed into a circle, a rectangle, or a triangle in a top view.

In some embodiments, the diverging structure includes a pillar, and an orthogonal projection of the pillar on the second photoelectric conversion element divides the second photoelectric conversion element into two regions, so that refraction occurs when light passes through the pillar.

In some embodiments, the orthogonal projection of the pillar on the second photoelectric conversion element is a hollow circular pattern or a hollow square pattern.

In some embodiments, the refractive index of the diverging structure is greater than the refractive index of air.

In some embodiments, the refractive index of the diverging structure is in a range from 1.2 to 2.5.

In some embodiments, the diverging structure includes first pillars and second pillars disposed above the first pillars.

In some embodiments, the diverging structure further includes an intermediate layer disposed between the first pillars and the second pillars and between the first pillars.

In some embodiments, each first pillar has a different diameter than each second pillar.

In some embodiments, the refractive index of the first pillars is different from the refractive index of the second pillars.

In some embodiments, there are first photoelectric conversion elements and one second photoelectric conversion element define pixels having the same size.

In some embodiments, the first photoelectric conversion elements surround the second photoelectric conversion element.

In some embodiments, eight first photoelectric conversion elements and one second photoelectric conversion element define nine pixels that form a 3×3 array, one of the pixels in the center corresponds to the second photoelectric conversion element and the diverging structure, and others of the pixel in the periphery correspond to the eight first photoelectric conversion elements and the converging structure.

In some embodiments, the first photoelectric conversion element defines a first pixel, the second photoelectric conversion element defines a second pixel, and the first pixel is larger than the second pixel.

In some embodiments, there are four first photoelectric conversion elements, and the second photoelectric conversion element is surrounded by the four first photoelectric conversion elements.

In some embodiments, the diverging structure inculudes pillars, and the pillars are diagonally arranged and correspond to two diagonal lines formed by the four first photoelectric conversion elements.

In some embodiments, the converging structure is a convex micro lens.

In some embodiments, the thickness of the diverging structure is greater than or equal to the thickness of the converging structure.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1A is a partial cross-sectional view illustrating the solid-state image sensor according to some embodiments of the present disclosure.

FIG. 1B is a partial top view illustrating the solid-state image sensor according to some embodiments of the present disclosure.

FIG. 2A to FIG. 2D are enlarged views of region E in FIG. 1B according to some embodiments of the present disclosure.

FIG. 3A to FIG. 3E are partial cross-sectional views illustrating a method for forming the solid-state image sensor at various stages according to some embodiments of the present disclosure.

FIG. 4 is a partial cross-sectional view illustrating the solid-state image sensor according to some other embodiments of the present disclosure.

FIG. 5 is a partial cross-sectional view illustrating the solid-state image sensor according to some other embodiments of the present disclosure.

FIG. 6 is a partial top view illustrating the solid-state image sensor 106 according to some other embodiments of the present disclosure.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed.

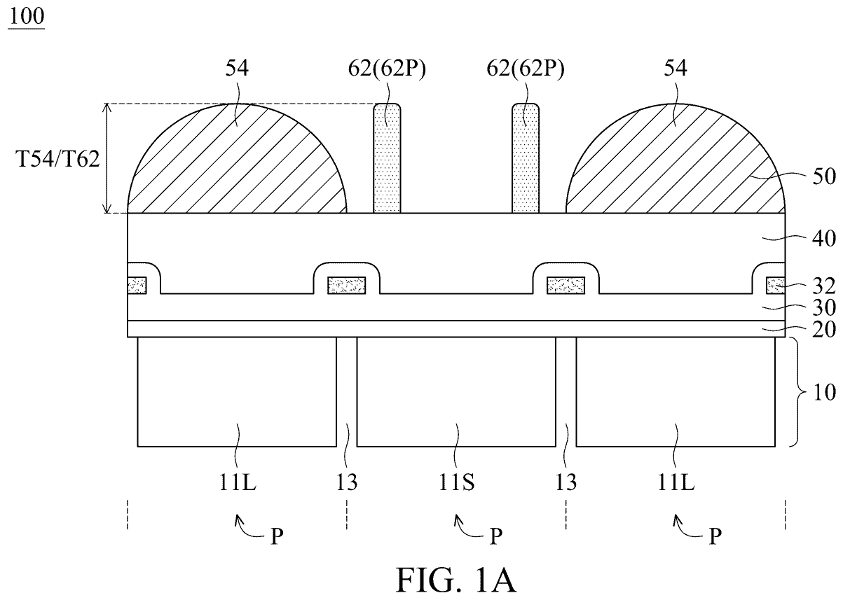

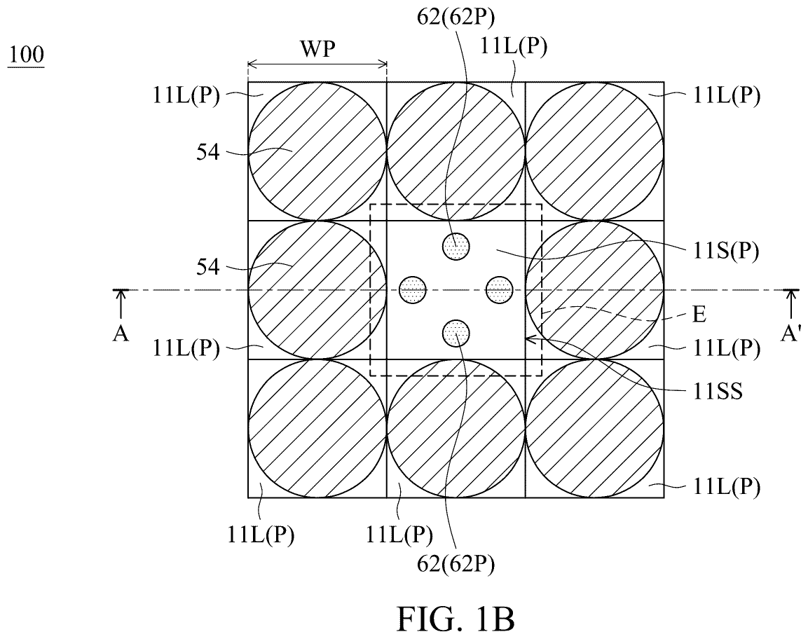

FIG. 1A is a partial cross-sectional view illustrating the solid-state image sensor 100 according to some embodiments of the present disclosure. FIG. 1B is a partial top view illustrating the solid-state image sensor 100 according to some embodiments of the present disclosure. For example, FIG. 1A may be the partial cross-sectional view of solid-state image sensor 100 along line A-A′ in FIG. 1B, but the present disclosure is not limited thereto. It should be noted that some components of the solid-state image sensor 100 have been omitted in FIG. 1A and FIG. 1B for the sake of brevity.

Here, the solid-state image sensor 100 may be a complementary metal-oxide semiconductor (CMOS) image sensor or a charge coupled device (CCD) image sensor, but the present disclosures is not limited thereto. As shown in FIG. 1A, in some embodiments, the solid-state image sensor 100 a semiconductor substrate 10 which may be, for example, a wafer or a chip, but the present disclosure is not limited thereto. As shown in FIG. 1A, multiple photoelectric conversion elements (e.g., photodiodes) may be formed in the semiconductor substrate 10.

Referring to FIG. 1A, in some embodiments, the solid-state image sensor 100 includes a first photoelectric conversion element 11L and a second photoelectric conversion element 11S that is adjacent to the first photoelectric conversion element 11L. Moreover, the first photoelectric conversion element 11L and the second photoelectric conversion element 11S may be isolated from each other by isolation structures 13 such as deep trench isolation (DTI) regions or shallow trench isolation (STI) regions. The isolation structures 13 may be formed in the semiconductor substrate 10 using etching process to form trenches and filling the trenches with an insulating or dielectric material.

As shown in FIG. 1A, the solid-state image sensor 100 may include a high dielectric-constant (high-K) film 20 disposed on the semiconductor substrate 10 and covering the first photoelectric conversion element 11L and the second photoelectric conversion element 11S. For example, the high-K film 20 may include hafnium oxide (HfO₂), hafnium tantalum oxide (HfTaO), hafnium titanium oxide (HfTiO), hafnium zirconium oxide (HfZrO), tantalum pentoxide (Ta₂O₅), any other suitable high-K dielectric material, or a combination thereof, but the present disclosure is not limited thereto. The high-K film 20 may be formed by a deposition process. The deposition process is, for example, chemical vapor deposition (CVD), plasma enhanced chemical vapor deposition (PECVD), atomic layer deposition (ALD), or another deposition technique. The high-K film 20 may have a high-refractive index and a light-absorbing ability.

As shown in FIG. 1A, the solid-state image sensor 100 may include a buffer layer 30 disposed on the high-K film 20. For example, the buffer layer 30 may include silicon oxides, silicon nitrides, silicon oxynitrides, any other suitable insulating material, or a combination thereof, but the present disclosure is not limited thereto. The buffer layer 30 may be formed by a deposition process. The deposition process is, for example, spin-on coating, chemical vapor deposition, flowable chemical vapor deposition (FCVD), plasma enhanced chemical vapor deposition, physical vapor deposition (PVD), or another deposition technique.

As shown in FIG. 1A, the solid-state image sensor 100 may further include a metal grid structure 32 disposed in the buffer layer 30 and corresponding to the isolation structures 13. For example, the metal grid structure 32 may include tungsten (W), aluminum (Al), metal nitride (e.g., titanium nitride (TiN)), any other suitable material, or a combination thereof, but the present disclosure is not limited thereto. The metal grid structure 32 may be formed by a deposition process and a patterning process, but the present disclosure is not limited thereto.

Referring to FIG. 1A, in some embodiments, the solid-state image sensor 100 includes a color filter layer 40 disposed above the first photoelectric conversion element 11L and the second photoelectric conversion element 11S. In more detail, the color filter layer 40 may be disposed on the buffer layer 30, but the present disclosure is not limited thereto. The color filter layer 40 may be formed by a deposition process. Examples of the deposition process have been described above and will not be repeated here.

Referring to FIG. 1A, in some embodiments, the solid-state image sensor 100 includes a converging structure 54 and a diverging structure 62 disposed on the color filter layer 40. The converging structure 54 corresponds to the first photoelectric conversion element 11L, and the diverging structure 62 corresponds to the second photoelectric conversion element 11S. In other words, the converging structure 54 is disposed above the first photoelectric conversion element 11L, and the diverging structure 62 is disposed above the second photoelectric conversion element 11S. As shown in FIG. 1A, in some embodiments, the thickness T62 of the diverging structure 62 is substantially equal to the thickness T54 of the converging structure 54, but the present disclosure is not limited thereto.

In some embodiments, the converging structure 54 is a convex micro lens. For example, the converging structure 54 may include a transparent material, such as glass, epoxy resin, silicone resin, polyurethane, any other applicable material, or a combination thereof, but the present disclosure is not limited thereto. The converging structure 54 may be formed by a photoresist reflow method, a hot embossing method, any other applicable method, or a combination thereof.

In the embodiment shown in FIG. 1A, the converging structure 54 is a semi-convex lens or a convex lens, but the present disclosure is not limited thereto. In some other embodiments, the converging structure 54 may be a micro-pyramid structure (e.g., circular cone, quadrangular pyramid, and so on), or a micro-trapezoidal structure (e.g., flat top cone, truncated square pyramid, and so on). Alternatively, the converging structure 54 may be a gradient-index structure.

FIG. 1B merely shows the first photoelectric conversion element 11L, the second photoelectric conversion element 11S, the converging structure 54, and the diverging structure 62 for the sake of brevity. As shown in FIG. 1A and FIG. 1B, in some embodiments, the diverging structure 62 includes pillars 62P. For example, the pillars 62P may include materials that are the same as or similar to the converging structure 54, but the present disclosure is not limited thereto. In some embodiments, pillars 62P are solid transparent cubes. In some embodiments, the refractive index of the diverging structure 62 is greater than the refractive index of air. In some embodiments, the refractive index of the diverging structure 62 is in a range from about 1.2 to about 2.5.

As shown in FIG. 1A and FIG. 1B, in some embodiments, multiple first photoelectric conversion elements 11L and one second photoelectric conversion element 11S define pixels P that have the same size. For example, the width WP of the pixel P may be about 2 μm, but the present disclosure is not limited thereto. As shown in FIG. 1B, in some embodiments, the first photoelectric conversion elements 11L surround the second photoelectric conversion element 11S.

As shown in FIG. 1B, in some embodiments, eight first photoelectric conversion elements 11L and one second photoelectric conversion element 11S define nine pixels P that form a 3×3 array. In other words, one of the pixels P in the center corresponds to the second photoelectric conversion element 11S and the diverging structure 62 (e.g., pillars 62P), and others of the pixel P in the periphery correspond to the eight first photoelectric conversion elements 11L and the converging structure 54 (e.g., convex micro lens) in this embodiment.

In some embodiments, the pillars 62P are arranged symmetrically in a top view (e.g., FIG. 1B). In this embodiment, the number of pillars 62P that correspond to one pixel P is four, but the present disclosure is not limited thereto. The number of pillars 62P may be changed as needed. Moreover, in some embodiments, each pillar 62P is disposed adjacent to the center of each side 11SS of the second photoelectric conversion element 11S in a top view (e.g., FIG. 1B). In other words, the pillars 62P may be horizontally and vertically arranged in FIG. 1B, but the present disclosure is not limited thereto. Diffraction occurs when light passes through the diverging structure 62 due to the arrangement of the pillars 62P, thereby changing the path of the light.

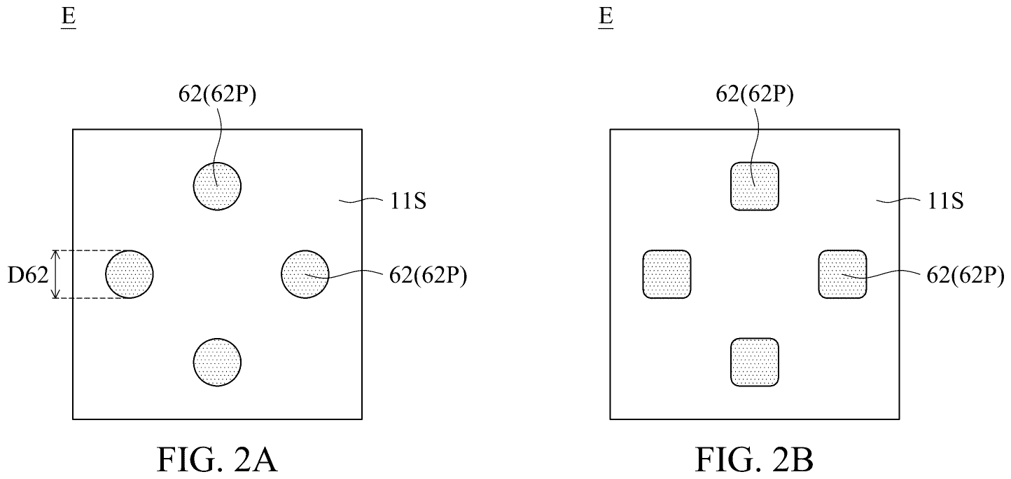

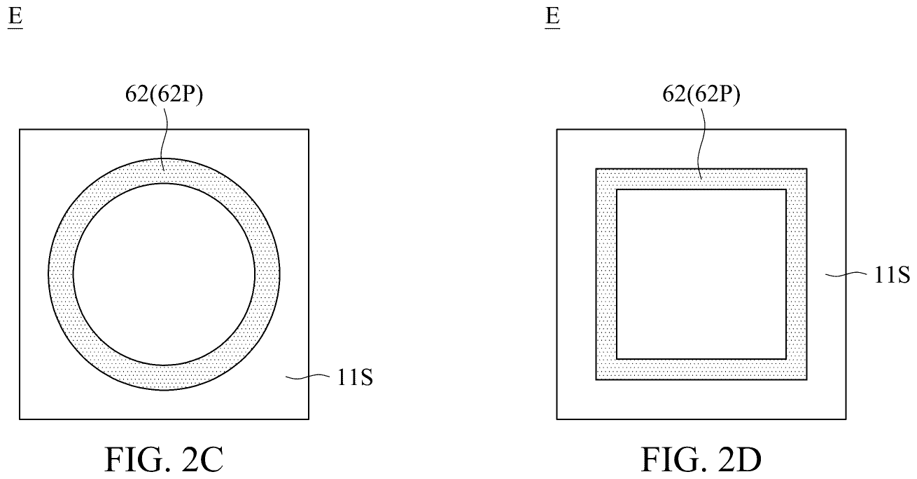

FIG. 2A to FIG. 2D are enlarged views of region E in FIG. 1B according to some embodiments of the present disclosure. As shown in FIG. 2A, each pillar 62P is formed into a circle in a top view. For example, the diameter of the circle may be greater than about 300 nm, but the present disclosure is not limited thereto. As shown in FIG. 2B, each pillar 62P is formed into a rectangle in a top view. Alternatively, each pillar 62P is formed into a triangle in a top view. In the embodiments show in FIG. 2A and FIG. 2B, diffraction occurs when light passes through the pillars 62P, thereby changing the path of the light.

In some embodiments, the degree of diffraction is affected by the thickness T62, the dimension D62, and refractive index of the cylinder of the diverging structure 62 (i.e., pillar 62P). The refractive index of the diverging structure 62 has a greater impact than the dimension D62 of the diverging structure 62, and the dimension D62 of the diverging structure 62 has a greater impact than the thickness T62 of the diverging structure 62.

In some embodiments, the diverging structure includes one pillar 62P, and an orthogonal projection of the pillar 62P on the second photoelectric conversion element 11S divides the second photoelectric conversion element 11S into two regions. As shown in FIG. 2C, the orthogonal projection of the pillar 62P on the second photoelectric conversion element 11S is a hollow circular pattern in a top view. As shown in FIG. 2D, the orthogonal projection of the pillar 62P on the second photoelectric conversion element 11S is a hollow square pattern in a top view. Alternatively, the orthogonal projection of the pillar 62P on the second photoelectric conversion element 11S may be any other pattern (e.g., a hollow triangular pattern, a hollow hexagonal pattern, or the like) that divides the second photoelectric conversion element 11S into at least two regions in a top view. In the embodiments show in FIG. 2C and FIG. 2D, refraction occurs when light passes through the pillar 62P, thereby changing the path of the light.

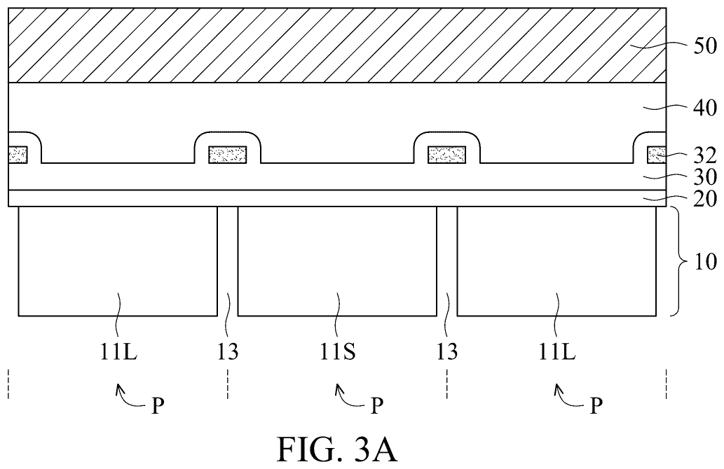

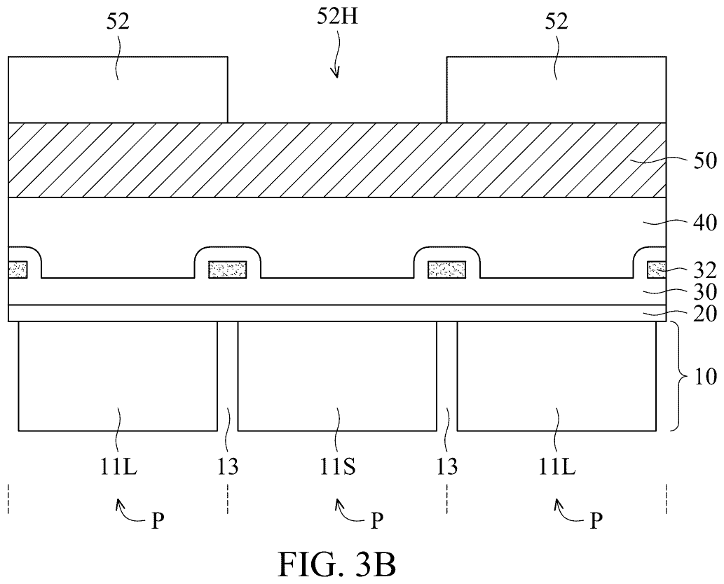

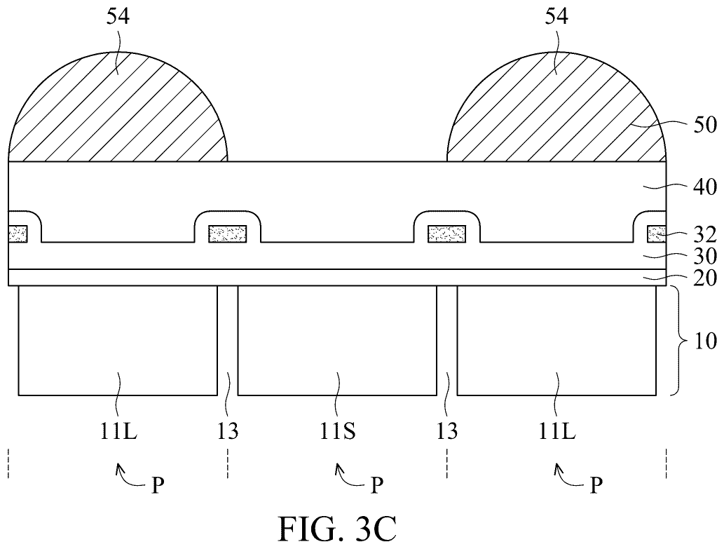

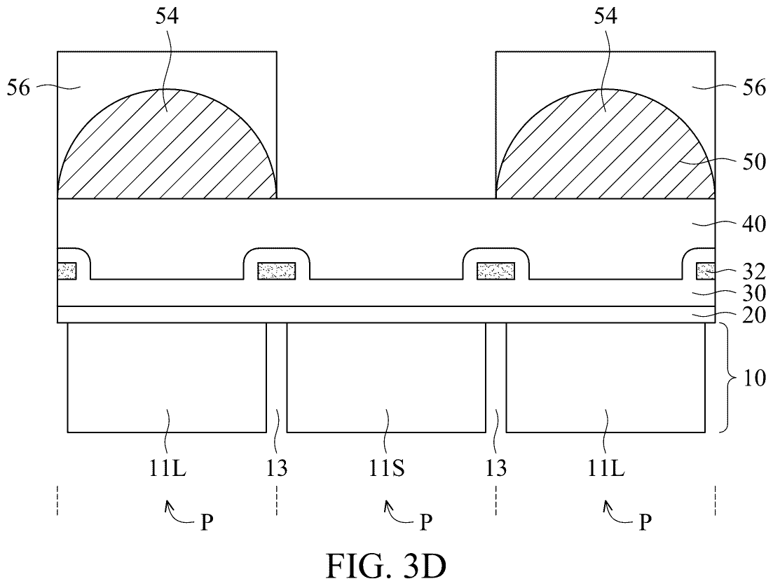

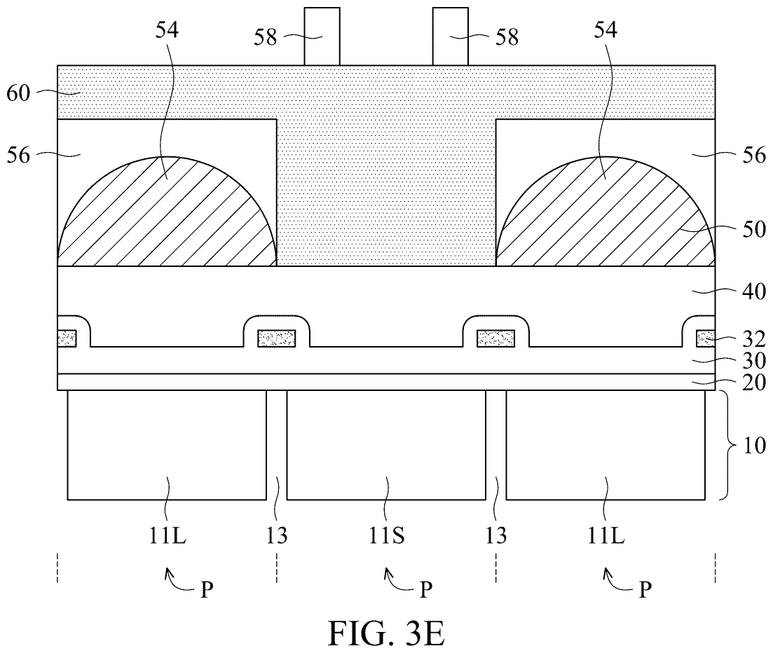

FIG. 3A to FIG. 3E are partial cross-sectional views illustrating a method for forming the solid-state image sensor 100 at various stages according to some embodiments of the present disclosure. Similarly, some components of the solid-state image sensor 100 have been omitted in FIG. 3A to FIG. 3E for the sake of brevity.

As shown in FIG. 3A, a high-K film 20 film 20 is formed on the semiconductor substrate 10, for example, by a deposition process. Here, the semiconductor substrate 10 includes a first photoelectric conversion element 11L and a second photoelectric conversion element 11S that is adjacent to the first photoelectric conversion element 11L. Moreover, the isolation structures 13 are disposed between the first photoelectric conversion element 11L and the second photoelectric conversion element 11S, and the high-k film 20 covers the first photoelectric conversion element 11L and the second photoelectric conversion element 11S.

As shown in FIG. 3A, a buffer layer 30 is formed on the high-K film 20, for example, by a deposition process. Here, a metal grid structure 32 may also be formed in the buffer layer 30 and correspond to the isolation structures 13. Then, a color filter layer 40 is formed on the buffer layer 30, for example, by a deposition process. Then, a transparent material 50 is formed on the color filter layer 40, for example, by a deposition process.

As shown in FIG. 3B, a mask layer 52 is formed on the transparent material 50, and then an etching process is performed to etch the transparent material 50 using the mask layer 52 as an etch mask. For example, the mask layer 52 may include a photoresist, such as a positive photoresist or a negative photoresist. Alternately, the mask layer 52 may be a hard mask and may include silicon oxide (SiO₂), silicon nitride (SiN), silicon oxynitride (SiON), silicon carbide (SiC), silicon carbonitride (SiCN), the like, or a combination thereof. The mask layer 52 may be a single layer or a multilayer structure any has a hole 52H.

The mask layer 52 may be formed by a deposition process, a photolithography process, any other suitable process, or a combination thereof. For example, the deposition process includes spin-on coating, chemical vapor deposition (CVD), atomic layer deposition (ALD), the like, or a combination thereof. For example, the photolithography process may include photoresist coating (e.g., spin coating), soft baking, mask aligning, exposure, post-exposure baking (PEB), developing, rinsing, drying (e.g., hard baking), any other suitable process, or a combination thereof.

The etching process may include a dry etching process, a wet etching process, or a combination thereof. For example, the dry etching process may include reactive ion etch (RIE), inductively-coupled plasma (ICP) etching, neutral beam etch (NBE), electron cyclotron resonance (ERC) etching, the like, or a combination thereof. For example, the wet etching process may use, for example, hydrofluoric acid (HF), ammonium hydroxide (NH₄OH), or any suitable etchant.

As shown in FIG. 3C, the converging structure 54 is formed to correspond to the first photoelectric conversion element 11L. For example, a reflow process may be performed to form the converging structure 54, but the present disclosure is not limited thereto.

As shown in FIG. 3D, a stop layer 56 is formed on the converging structure 54, so that the stop layer 56 may cover the converging structure 54.

As shown in FIG. 3E, another transparent material 60 is formed on the stop layer 56, for example, by a deposition process. Another mask layer 58 is formed on transparent material 60, and then an etching process is performed to etch the transparent material 60 using the mask layer 58 as an etch mask. Here, the mask layer 58 corresponds to the second photoelectric conversion element 11S, so that the diverging structure 62 (the pillars 62P) as shown in FIG. 1A is formed above the second photoelectric conversion element 11S after the etching process.

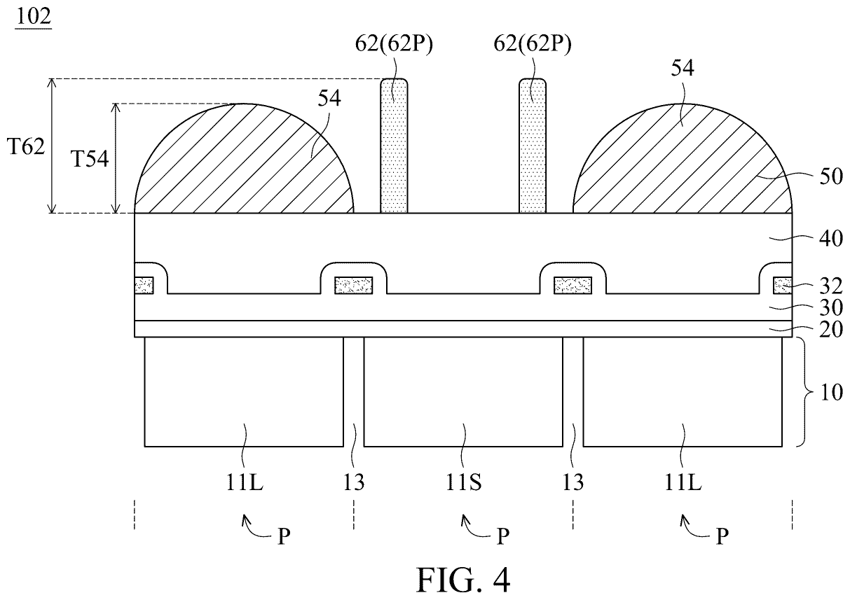

FIG. 4 is a partial cross-sectional view illustrating the solid-state image sensor 102 according to some other embodiments of the present disclosure. The top view of the solid-state image sensor 102 may be the same as or similar to the solid-state image sensor 100 shown in FIG. 1B. Similarly, some components of the solid-state image sensor 102 have been omitted in FIG. 4 for the sake of brevity.

The solid-state image sensor 102 shown in FIG. 4 has a similar structure to the solid-state image sensor 100 shown in FIG. 1A. The main difference from the solid-state image sensor 100 is that the thickness T62 of the diverging structure 62 is substantially greater than the thickness T54 of the converging structure 54 in the embodiment shown in FIG. 4, but the present disclosure is not limited thereto.

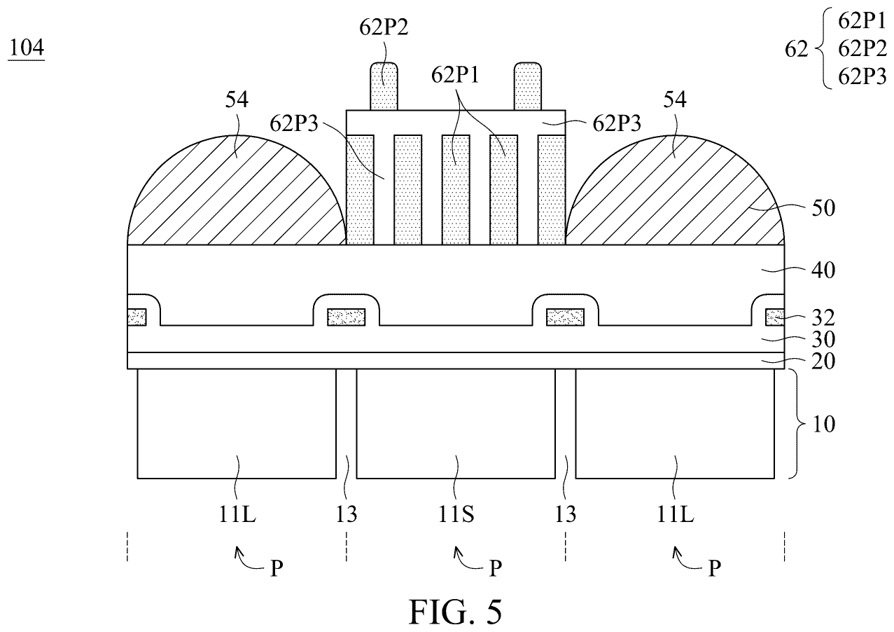

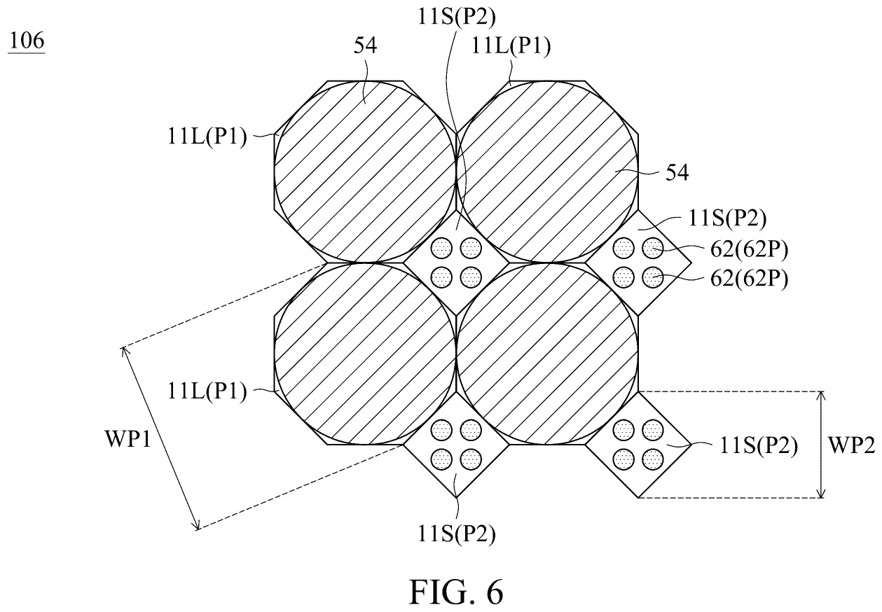

FIG. 5 is a partial cross-sectional view illustrating the solid-state image sensor 104 according to some other embodiments of the present disclosure. The top view of the solid-state image sensor 104 may be the same as or similar to the solid-state image sensor 100 shown in FIG. 1B. Similarly, some components of the solid-state image sensor 104 have been omitted in FIG. 5 for the sake of brevity.

The solid-state image sensor 104 shown in FIG. 5 has a similar structure to the solid-state image sensor 100 shown in FIG. 1A. The main difference from the solid-state image sensor 100 is that the diverging structure 62 of the solid-state image sensor 104 shown in FIG. 5 includes first pillars 62P1 and second pillars 62P2 that are disposed above the first pillars 62P1. That is, the diverging structure 62 may be a multi-layer pillar structure. In some embodiments, the refractive index of the first pillars 62P1 is different from the refractive index of the second pillars 62P2. In some embodiments, each first pillar 62P1 has a different diameter than each second pillar 62P2, such that light may be deflected to different degrees when passing through the second pillars 62P2 and the first pillars 62P1.

In some embodiments, the diverging structure 62 further includes an intermediate layer 62P3 disposed between the first pillars 62P1 and the second pillars 62P2 and between the first pillars 62P1. For example, the intermediate layer 62P3 may include a different material from the first pillars 62P1 and the second pillars 62P2, but the present disclosure is not limited thereto. As shown in FIG. 5, the intermediate layer 62P3 is disposed on top portions of the first pillars 62P1 and connects the top portions of the first pillars 62P1 and the bottom portions of the second pillars 62P2 to support the second pillars 62P2, but the present disclosure is not limited thereto. Moreover, the intermediate layer 62P3 is disposed between the first pillars 62P1. Here, the first pillars 62P1 and the second pillars 62P2 may be substantially perpendicular to the (top surface of) color filter layer 40, but the present disclosure is not limited thereto. The intermediate layer 62P3 may be used to further separate the first pillars 62P1 and support the second pillars 62P2.

FIG. 6 is a partial top view illustrating the solid-state image sensor 106 according to some other embodiments of the present disclosure. Similarly, some components of the solid-state image sensor 106 have been omitted in FIG. 6 for the sake of brevity.

As shown in FIG. 6, in some embodiments, the first photoelectric conversion element 11L defines a first pixel P1, the second photoelectric conversion element 11S defines a second pixel P2, and the first pixel P1 is substantially larger than the second pixel P2. For example, the maximum width WP1 of the first pixel P1 is greater than the maximum width WP2 of the second pixel P2.

As shown in FIG. 6, in some embodiments, there are multiple first photoelectric conversion elements 11L and multiple second photoelectric conversion elements 11S, and each second photoelectric conversion element 11S is surrounded by four first photoelectric conversion elements 11L, but the present disclosure is not limited thereto.

Similarly, in some embodiments, each pillar 62P is disposed adjacent to the center of each side of the second photoelectric conversion element 11S in a top view (e.g., FIG. 6). In other words, the pillars 62P are diagonally arranged and correspond to two diagonal lines formed by the four first photoelectric conversion elements as shown in the embodiment of FIG. 6, but the present disclosure is not limited thereto.

As noted above, the solid-state image sensor according to the embodiments of the present disclosure includes a converging structure and a diverging structure respectively corresponding to different photoelectric conversion elements. This effectively enhances the signal difference of the photoelectric conversion elements (such as enhances 8.6%), thereby achieving a high dynamic range.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. A solid-state image sensor, comprising:
a first photoelectric conversion element;
a second photoelectric conversion element adjacent to the first photoelectric conversion element;
a color filter layer disposed above the first photoelectric conversion element and the second photoelectric conversion element;
a converging structure disposed on the color filter layer and corresponding to the first photoelectric conversion element; and
a diverging structure disposed on the color filter layer and corresponding to the second photoelectric conversion element.

2. The solid-state image sensor as claimed in claim 1, wherein the diverging structure comprises pillars.

3. The solid-state image sensor as claimed in claim 2, wherein the number of the pillars is four, and the four pillars are arranged symmetrically and adjacent to centers of four sides of the second photoelectric conversion element in a top view, so that diffraction occurs when light passes through the pillars.

4. The solid-state image sensor as claimed in claim 2, wherein the pillars are solid transparent cubes, and each of the pillars is formed into a circle, a rectangle, or a triangle in a top view.

5. The solid-state image sensor as claimed in claim 1, wherein the diverging structure comprises a pillar, and an orthogonal projection of the pillar on the second photoelectric conversion element divides the second photoelectric conversion element into two regions, so that refraction occurs when light passes through the pillar.

6. The solid-state image sensor as claimed in claim 5, wherein the orthogonal projection of the pillar on the second photoelectric conversion element is a hollow circular pattern or a hollow square pattern.

7. The solid-state image sensor as claimed in claim 1, wherein a refractive index of the diverging structure is greater than a refractive index of air.

8. The solid-state image sensor as claimed in claim 1, wherein a refractive index of the diverging structure is in a range from 1.2 to 2.5.

9. The solid-state image sensor as claimed in claim 1, wherein the diverging structure comprises:
first pillars; and
second pillars disposed above the first pillars.

10. The solid-state image sensor as claimed in claim 9, wherein the diverging structure further comprises:
an intermediate layer disposed between the first pillars and the second pillars and between the first pillars.

11. The solid-state image sensor as claimed in claim 9, wherein each of the first pillars has a different diameter than each of the second pillars.

12. The solid-state image sensor as claimed in claim 9, wherein a refractive index of the first pillars is different from a refractive index of the second pillars.

13. The solid-state image sensor as claimed in claim 1, wherein there are first photoelectric conversion elements and one second photoelectric conversion element that define pixels having the same size.

14. The solid-state image sensor as claimed in claim 13, wherein the first photoelectric conversion elements surround the second photoelectric conversion element.

15. The solid-state image sensor as claimed in claim 13, wherein eight first photoelectric conversion elements and one second photoelectric conversion element define nine pixels that form a 3×3 array, one of the pixels in the center corresponds to the second photoelectric conversion element and the diverging structure, and others of the pixel in the periphery correspond to the eight first photoelectric conversion elements and the converging structure.

16. The solid-state image sensor as claimed in claim 1, wherein the first photoelectric conversion element defines a first pixel, the second photoelectric conversion element defines a second pixel, and the first pixel is larger than the second pixel.

17. The solid-state image sensor as claimed in claim 16, wherein there are four first photoelectric conversion elements, and the second photoelectric conversion elements is surrounded by the four first photoelectric conversion elements.

18. The solid-state image sensor as claimed in claim 17, wherein the diverging structure comprises pillars, and the pillars are diagonally arranged and correspond to two diagonal lines formed by the four first photoelectric conversion elements.

19. The solid-state image sensor as claimed in claim 1, wherein the converging structure is a convex micro lens.

20. The solid-state image sensor as claimed in claim 1, wherein a thickness of the diverging structure is greater than or equal to a thickness of the converging structure.
